(19) United States
(12) Patent Application Publication
(10) Pub. No.: US 2026/0246239 A1
(43) Pub. Date: Aug. 20, 2026

(54) SURFACE EMITTING LASER, METHOD FOR FABRICATING SURFACE EMITTING LASER

(71) Applicant: SANOH INDUSTRIAL CO., LTD., Tokyo (JP)

(72) Inventor: Srinivas Gandrothula, Koga-shi, Ibaraki (JP)

(21) Appl. No.: 19/160,811

(22) PCT Filed: Mar. 7, 2023
(86) PCT No.: PCT/JP2023/008680

§ 371 Date: Aug. 28, 2025

(51) Int. Cl. H01S 5/343; H01S 5/183

(52) U.S. Cl. CPC H01S 5/343; H01S 5/18361; H01S 2304/00

(57) ABSTRACT

An extended vertical cavity surface emitting laser (VCSEL) includes: an epitaxially laterally overgrown semiconductor section, a III-nitride active region between hole injecting III-nitride layer and an electron injecting III-nitride layer; and a nanoporous III nitride layer on the electron injecting III nitride layer side.

### TECHNICAL FIELD

This invention relates to a III-nitride vertical cavity surface emitting laser (VCSEL) with nanoporus GaN DBR and a method of fabricating a III-nitride VCSEL with nanoporus GaN DBR.

### BACKGROUND ART

This application references a number of patent or non-patent publications as indicated throughout the specification by their reference numbers within brackets, i.e., []. A list of the publications ordered according to these reference numbers can be found below in the section entitled “Non Patent Literature” or “Patent literature”.

### CITATION LIST

### Non Patent Literature

NPL 1: Appl. Phys. Lett. 92, 141102 (2008 )

NPL 2: Appl. Phys. Express 12, 044004 (2019)

NPL 3: Sci. Rep. 8, 10350 (2018 )

NPL 4: Jpn. J. Appl. Phys. 58, SC 0806 (2019 )

NPL 5: Appl. Phys. Express 11, 112101 (2018)

NPL 6: Appl. Phys. Lett. 101, 151113 (2012)

NPL 7: ACS Photonics, 2 980-986 (2015)

NPL 8: Sci. Rep. 7, 45344 (2017 )

NPL 9: Appl. Phys. Lett. 112, 041109 (2018)

NPL 10: Scr. Mater, 156, 10-13 (2018)

NPL 11: Appl. Phys. Express 2012, 5, 092104

NPL 12: Optics Express, 27, 24717 (2019)

NPL 13: Appl. Phys. Express, 13, 041003 (2020)

NPL 14: Appl. Phys. Express, 14,031002 (2021)

NPL 15: Applied Phys. Lett. 119, 142103 (2021)

NPL 16: Crystals, 11 (12) 1563, (2021)

NPL 17: M. B. Stern and T. R. Jay, “Dry etching for coherent refractive microlens arrays,” Opt. Eng. 33, 3547-3551 (1994)

Surface emitting lasers are known as vertical cavity surface emitting lasers (VCSELs). A VCSEL comprises a semiconductor active region disposed between an n-side semiconductor region and a p-side semiconductor region, and two distributed Bragg reflectors, which are referred to as DBRs, acting as high reflective mirrors. The semiconductor active region, also known as a gain medium, is disposed between the two DBRs such that the two DBRs and the semiconductor active region form an optical cavity. The n-side and p-side regions inject respective carriers, i.e., electron and hole, to the active region, and these carriers recombine in the active region to generate light. The light or electromagnetic radiation thus generated is reflected a number of times by the DBRs to travel in the optical cavity, leading to lasing. The VCSEL provides one of the DBRs with a less reflectance mirror, which is used to emit the laser beam.

Gallium nitride (GaN) VCSELs have recently been receiving increasing research attention due to their ability to emit in the visible and ultraviolet (UV) regions. This opens up a variety of new application space in displays, solid state lighting including automotive lighting and residential lighting, sending and communications. One particularly most exciting application is when blue emitting GaN VCSELs could couple with phosphor to act as a both natural light emitting source and data transmission device simultaneously. This application would address the all the new AR/VR ap-plications, smartphone and normal displays in a new dimension by adding a communication feature to each light emitting pixel.

GaAs-based Infra-red VCSELs have adopted a matured manufacturing technique, on the other hand III-nitride based VCSELs still lacking industrial feasibility due to technical challenges such as conductive dielectric Bragg reflector (DBR). Continuous-wave (CW) lasing at 462 nm of electrically injected GaN VCSEL was first demonstrated in 2008 at a temperature of 77K [NPL 1]. Since then, considerable progress has been made in terms of output power, efficiency, threshold current, lasing wavelength, and room temperature stability. However, industrial adoption still not achieved. As above mentioned, one of the problems is n-side DBR mirror, which is in general dielectric DBR causing thermal instability in the device operation. Conventionally, a dielectric DBR is deposited on the n-side of the VCSEL after laboriously polishing off the host substrate. Alternative approaches such as epitaxial DBRs, nanoporous GaN DBRs have been grown on top of the host substrate, and long optical GaN cavity VCSELs were proposed in the literatures for better thermal stability.

These approaches were great to a certain extent, but problems such as problems such as expensive GaN substrates, and after paying hefty price not availability of GaN substrates at larger size are the main problems to concern. On the other hand proposed epitaxial DBR method increases growth times and additionally preserving device layers quality is a bottleneck and the throwing an expensive GaN substrate for the cases such as long GaN cavity and nanoporous GaN DBR cavities need to be addressed.

VCSEL with a long optical cavity and the curved lens refocuses electric filed into the gain medium there by reducing diffraction loses that originate from the longer cavity length [NPL 2-NPL 4]. Up until 2022, long cavity designs from Sony held the performance records for CW output power power of 15.8 mW, threshold current 0.25 mA, and wall plug efficiency (WPE) 9.5%. Long-optical GaN cavity VCSEL designs have accomplished impressive results by utilizing significant portion of the host substrate in the cavity design. Substrate is redesigned to curved mirror after grinding away the unnecessary portion, which is again a laborious and both time and money consuming process. In the long optical cavity designs, the curved mirror is necessary because it prevents diffraction and scattering loss. The typical gain of active region in the nitride VCSEL is ~1%, so in long optical GaN cavity diffraction loss can quickly deteriorates device performance for cavities larger than 10 micrometers. Sony curved mirror VCSEL cavity is ~28 micrometers. This will briefly be giving a peak into the amount of difficulty involved in polishing with cavities nearing towards active region. This procedure possess restriction on increased GaN cavity.

On the other hand, epitaxial designs utilizing AlGaN/GaN or AlInN/GaN mirror pairs have also been on radar recent times especially [NPL 05-NPL 06], the later showing a superior performance due to ability of AlInN lattice match to GaN.

However, requiring ~40 or more periods of AlInN/GaN layers to reach a reasonable reflectivity (>99.5% for emission side) and equally maintaining sensitive growth conditions for better quality and improved yields can make epitaxial DBR designs difficult to realize.

And most recently, nanoporous GaN DBR (NP-GaN DBR) designs [NPL 7-NPL 10] have also been gaining traction due to their relative ease of fabrication, their lattice match to GaN and their high achievable refractive index contrast. Due to this high index contrast, a realistic porosity of 36% can achieve 99.5% reflectivity with only 17 periods. Since first NP-GaN DBRs first demonstrated in 2015, multiple groups have achieved lasing with NP-GaN DBR designs. NP-GaN DBR layers provide better thermal stability than dielectric DBR mirror. However, a common problem of thinning and grinding of expensive host GaN substrate after realizing NP-GaN DBR layers on the substrate persists.

It is necessary achieving better crystal quality for the device layers and a solution to obtain stability in terms of thermal draining to push nitride VCSELs towards manufacturing. Substrate removal techniques such as photo electro chemical (PEC) [NPL 11] and epitaxial lateral overgrowth (ELO) assisted thermal peel off [NPL 12-NPL 16] are the better options for future the VCSEL design. As large size foreign substrates can be utilized in the ELO method this would be more favorable option to design a hybrid-VCSEL consists of NP GaN DBR on n-side and a dielectric DBR on p-side.

### SUMMARY OF INVENTION

### Technical Problem

Considering all these disadvantages, an object of the present invention is to provide a III-nitride VCSEL with a nanoporous GaN DBR and a method of fabricating a III-nitride VCSEL with a nanoporous GaN DBR with improved device performance in terms of thermal and optical properties.

### Solution to Problem

To overcome the limitations of prior art described above, the present invention discloses a III-nitride-based VCSEL, comprising: a III-nitride active region between a p-type (hole injecting) III-nitride layer and an n-type (electron injecting) III-nitride layer; and a curved mirror or simply a flat dielectric mirror designed on or above p-side III-nitride layer.

ELO growth mechanism generally leads to a thicker III-nitride layer, but in our design a NP GaN DBR layers growth was carried after the thick ELO base unintentionally doped layer. Thus the actual thickness of the device layers, n-GaN, active region, p-AlGaN electron blocking layer and p-GaN layer, (and sometimes current spreading tunnel junction (p++/n++ GaN) ) can be controlled either for short optical cavity (<10 λ) or large cavity (>10 λ).

The VCSEL further comprises: one or more tunnel junction layers on the p-side III-nitride layer, wherein the curved mirror or flat dielectric mirror is formed on or above the tunnel-junction layers such that the tunnel junction layers are between the curved mirror and p-type III-nitride layer.

The VCSEL further comprises: a second n-type III-nitride region on or above the tunnel-junction layers, wherein curved or flat mirror includes the second n-type III-nitride region and the second type III-nitride region designed as lens or left as flat surface for the DBR mirror placement.

The second III-nitride n-type region functions as current spreading layer and has an etched surface having a curvature for long cavity VCSELs and is left as flat for short optical cavity VCSELs. The second type III-nitride region comprises n-type GaN or unintentionally doped GaN.

The VCSEL further comprise: one or more transparent conducting oxide (TCO) layers on p-type III-nitride layer as inter cavity contact layer, wherein the curved mirror is formed on or above the TCO layer. TCO layers may compose of ITO, ZnO.

In the case of long cavity case curved mirror comprises a dielectric material that is transparent, the dielectric material surface has a curvature, and a DBR composed of dielectric thin films is disposed upon the dielectric material surface.

Also, in the case of long cavity VCSEL, dielectric material (which is transparent oxide or a polymer) is removed by wet or dry etching after DBR deposition, and then fill the void with thermal conducting gas or leave it as void.

The VCSEL further comprises a periodic selectively doped GaN layers on or above ELO base layer. The selectively doped GaN layers are formed into NP-GaN flat DBR mirror in the process of VCSEL fabrication.

The VCSEL further comprises discrete island-like III-nitride ELO base layers, such that ease of accessibility for the chemicals of electrochemical etching is improved, wherein pores formation realized in the selectively doped GaN layers via electro chemical etching.

The NP-GaN layers are better in thermal and electrical conducting compared to dielectric DBR mirror.

Also, NP-GaN layers shares the same plane as the active layers, resulting configuration is a series of parallel NP-GaN layers separated with non-porous GaN layers. The flat DBR mirror in the VCSEL design is a nanoporous DBR layers.

Crystal orientation of III-nitride layers in the VCSEL may be c-plane, semipolar or non-polar.

### BRIEF DESCRIPTION OF DRAWINGS

FIG. 1A is a schematic, wherein: FIG. 1A shows a foreign substrate with III-nitride template.

FIG. 1B is a schematic, wherein: FIG. 1B shows a dielectric mask open area patterning to III-nitride growth layer.

FIG. 1C is a schematic, wherein: FIG. 1C shows a schematic of a stripes design to accommodate VCSEL devices on each.

FIG. 2A is a schematic after the growth of base ELO III-nitride layer.

FIG. 2B is a schematic to show edge growth on the ELO base.

FIG. 2C is schematic of planarized ELO base.

FIG. 3A is a schematic of the processed short cavity VCSEL design before taking off from host substrate.

FIG. 3B is processed VCSEL.

FIG. 3C is typical VCSEL chip both top and bird view.

FIG. 4A is a schematic of the processed long cavity VCSEL design with GaN lens before taking off from host substrate.

FIG. 4B is processed VCSEL with GaN lens.

FIG. 4C is processed VCSEL with dielectric lens.

FIG. 4D is processed VCSEL with air lens.

FIG. 4E is typical VCSEL chip both top and bird view.

### DESCRIPTION OF EMBODIMENTS

Teachings of the present invention can be readily understood by considering the following detailed description with reference to the accompanying drawings shown as examples. Referring to the accompanying drawings, a schematic view showing a vertical cavity surface emitting laser (VCSEL), and a method for fabricating a VCSEL according to the present disclosure will be described below. To facilitate understanding, identical reference numerals are used, where possible, to designate identical elements that are common to the figures.

In the following embodiments descriptions provided to the referenced drawings The use of NP-GaN DBR flat mirror over the ELO base layer and a curved or flat DBR mirror on p-side of III-nitride VCSEL are proposed to be a viable way to improve device performance in terms of thermal and optical.

### Technical Disclosure

The following disclosure is divided into four sections. The first section describes the ELO base layer preparation. The second section provides information on NP-GaN DBR and device layers growth. The third and fourth section respectively illustrates short and long cavity VCSELs.

### Section1: Preparation of ELO Base

The ELO method to form the island-like III-nitride semiconductor layers may include growth by metal organic chemical vapor deposition (MOCVD), hydride vapor phase epitaxy (HVPE), etc. The III-nitride semiconductor layers are dimensioned to create one or more of the island-like III-nitride semiconductor layers. Alternatively, the ELO III-nitride layers can made to coalesce initially, such that they can be later divided into individual devices.

ELO layer has two parts one is open region which generally have more defects compared to its counterpart extending onto an ELO mask. The counterpart extends both ways onto the ELO mask from open region termed them as ELO wings. The VCSEL light emitting aperture is made on the ELO wing. Moreover, the present invention can use hetero-substrates to grow the island-like III-nitride semiconductor layers that form the bar. For example, a GaN template grown on a hetero-substrate, such as Sapphire, Si, SiC, SiN, GaAs, Ga₂O₃, LiAlO₂, ScAlMgO₄ (SAM), etc., can be used in the present invention.

Furthermore, the ELO method can drastically reduce dislocation density and stacking faults density when non Basel GaN crystal planes used, which are critical issues when using hetero-substrates. Therefore, this invention can solve many kinds of problems incurred with the use of hetero-substrates, at the same time. For example, in a laser device, the interface between ELO mask and the III-nitride template layer can be made smooth such that light emission from the interface side will not be effected.

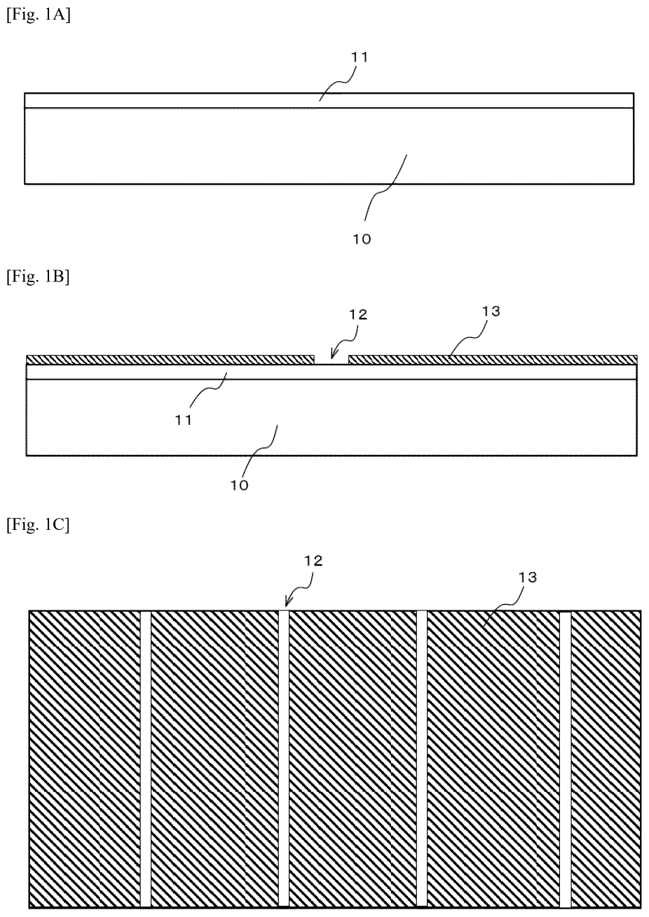

FIGS. 1A, 1B, and 1C are schematics that illustrate a method, which comprises providing a III-nitride-based substrate 10, such as a GaN-on-Si, GaN-on-Sapphire, GaN-on-ScAlMgO₄ (SAM) or bulk GaN substrate. In the case of a foreign substrate, a III-nitride template 11 can be deposited on the substrate 10, and the design of the template 11 can be a uniform layer over the host foreign substrate 10, or the template 11 can be designed only as an open area stripe 12. A III-nitride stripe 12 containing a host substrate 10, such as the stripes shown in the schematics of FIG. 1C. The open area stripes 12 can also be modified to be confined to a single device by shortening its length, or the open area stripes can also be modified to be confined to a plurality of devices by increasing its length.

As shown in the schematics of FIG. 1C, a dielectric mask 13 is formed on or above a GaN-based substrate 10. Specifically, the dielectric mask 13 is disposed directly in contact with the substrate 10 or is disposed indirectly through a template layer grown by MOCVD, etc., and made of III-nitride-based semiconductor deposited on the substrate 10 while leaving open area stripes 12.

The dielectric mask 13 can be formed from an insulator film, for example, an SiO₂ film or SiN, deposited upon the substrate 10, for example, by a plasma chemical vapor deposition (CVD), sputter, ion beam deposition (IBD), etc., wherein the SiO₂ film is then patterned by photolithography using a predetermined photo mask and etching to include opening areas as shown in FIGS. 1B and 1C. The designing of this dielectric film would have an immerse effect on the later device processing and operation.

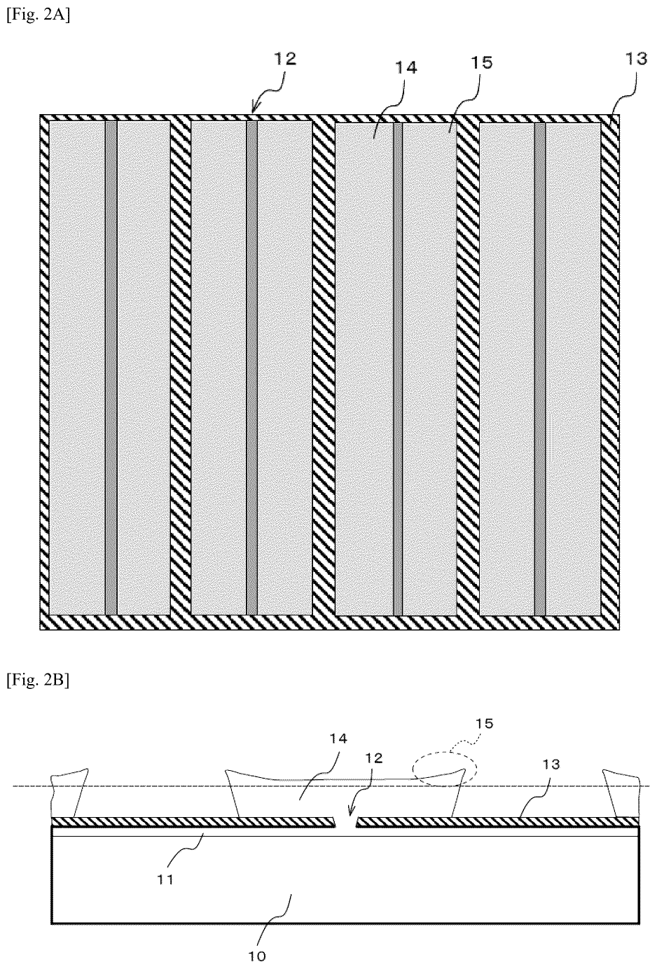

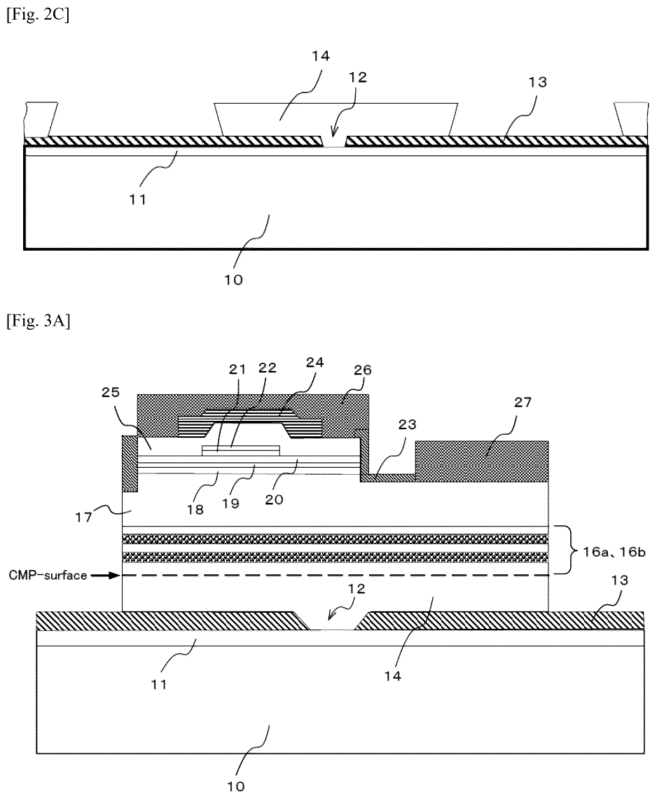

As shown in the schematics of FIGS. 2A, 2B and 2C, epitaxial III-nitride layers 14, such as GaN-based layers, are grown by ELO on the GaN based substrate and the dielectric mask 13. The growth of the ELO III-nitride layers 14 occurs first in the opening areas on the GaN-based substrate, and then laterally from the opening areas over the dielectric mask. The growth of the ELO III-nitride layers is stopped or interrupted before the ELO III-nitride layers from adjacent opening areas can coalesce on top of the dielectric mask. Alternatively, the growth of the ELO III-nitride layers may be continued and coalesce with neighboring ELO III-nitride layers. A wing 15 of the ELO III-nitride layers is an area of reduced defect density on either side of the opening areas. In the ELO growth method, wherein a fill factor, the ratio between open area and dielectric mask, is significantly deviates from unity resulting III-nitride atoms may accumulate more at the edge of the III-nitride layer compared to the central portion of the layer as shown in FIG. 2B. Which can be seen as edge growth may serve as a dis-advantage when continued for the growth of NP GaN layers and VCSEL device layers. In FIG. 2C, the III nitride ELO base layer thus deposited is optionally polished to obtain a planer surface. As these layers surface is achieved using epitaxial growth a little chemical mechanical polishing, or dry or wet etching should be enough to obtain planarized layers.

### Section 2: NP-GaN DBR and Device Layers Growth on ELO Base

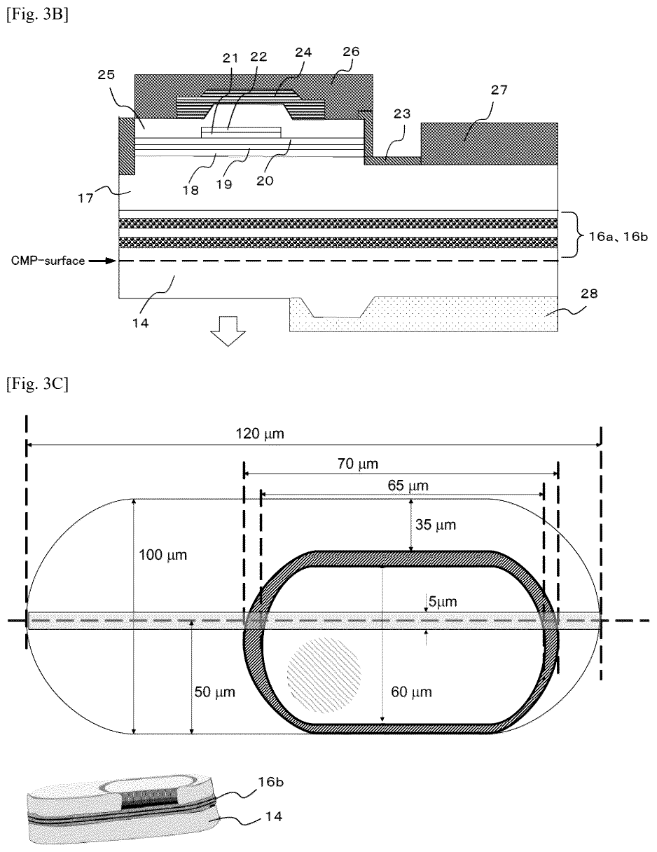

NP-GaN DBRs are promising solutions for the GaN based VCSELs, as they can provide better thermal stability compared to dielectric DBRs and their lattice match ability to GaN is a desirable condition for growth and fabrication, additionally NP-GaN DBRs provide high refractive index contrast. The formation of NP-GaN DBRs was extensively studied and the mechanism of etching was well understood. At a given applied bias, the size and shape of pores is controlled via n-type doping and crystal orientation of the exposed layers to the oxalic acid solution in electrochemical etching (EC). As the etching proceeds, first applied negative bias creates a hole inversion layer at the electrolyte/n-GaN interface, second the n-GaN surface is oxidized due to the presence of holes at the inverted surface, third oxidized GaN dissolves into Ga3+ and nitrogen gas and finally it migrates freely into the electrolyte leaving behind a void, called nanoporous. After the planarization of the III nitride layer 14, as shown in FIG. 3A, a semiconductor nanoporous GaN DBR section 16a, is grown over the ELO base layer. Nanoporous GaN DBR section includes periodic super lattice of unintentionally doped (UID) GaN and n+-GaN ([Si]~10¹⁹/cm³) then device layers include the III-nitride n-GaN 17 layer, the III nitride active layers 18, III-nitride p-type electron blocking layer (EBL) 19, the p-type III nitride layer 20 and the p⁺⁺ GaN layer 21. After this growth, the samples are treated with chemical solutions such as BHF and reintroduced in the MOCVD system for the growth of n⁺⁺ GaN 22 layer to finish tunnel junction.

Buried tunnel junction apertures are then defined by etching deep into the p-GaN 20 through n⁺⁺/p⁺⁺ GaN layers using reactive ion etching (RIE). Finally, n-GaN and UID GaN layers grown on top of the NP GaN layers. The newly regrown n-GaN and UID GaN layer thickness controllability results in either short cavity VCSEL or long cavity VCSEL.

There are namely three subcategories can be identified under long cavity VCSEL, (i) GaN lens, (ii) dielectric lens and (iii) air/gas lens. Initially formed NP GaN layers are later made into DBR mirror 16b, by using EC process described above. Thus, NP DBR layers non differentiable until they made into porous and non-porous layers by an electro-chemical etching process.

### Section 3: Short Cavity VCSELs

For example, in the case of short cavity VCSEL, after growing a super lattice of NP DBR assuming light emission designed from NP-GaN DBR so the porosity and the number of DBR layers optimized to achieve a value ~99.5. The device layers for a short cavity <10 λ thick were designed using n-GaN 17, active region 18, p-AlGaN 19 and p-GaN 20 and tunnel junction layers. Then a current spread layer (n-GaN) 25 to burry tunnel junction is prepared and fit all the design parameters as per the short cavity VCSEL requirement. Current injecting aperture is formally defined during burying process of tunnel junction, then after slightly large mesa is prepared to contact n-GaN layer 17 for the metal contact. This etched large mesa and discrete island nature of the ELO bars assist to activate p-type GaN more effectively. Then an isolation layer 23 is placed to avoid short circuit between p-contact layer 26 and n-contact layer 27. Then selectively a mesa is opened photolithographically on the top of the device centering the current aperture. After the patterning, a 16-period dielectric DBR 24 made of periods of SiO₂/Ta₂O₅ was deposited on the topside. Next, SiO₂ or a protective film was deposited (not shown) to protect devices from NP DBR etch and provide electrical isolation.

The optical reflectance of the DBR mirror 16b is lower than the optical reflectance of the dielectric DBR 24. For example, the optical reflectance of the DBR mirror 16b is 99.995 to 99.997. Further, for example, the optical reflectance of the dielectric DBR 24 is 99.998.

Next, EC etching was performed on the samples by immersing them in oxalic acid against a bias voltage to etch NP DBRs 16b. Then, p-contact and n-contact pads were selectively patterned by removing isolation layers using photolithography and then metal contacts Ti/Au were deposited. Next the VCSEL device is separated from the host substrate either by thermal peeling mentioned in or by laser or chemical lift off methods, resulting picture shown in FIG. 3B. Then, if necessary, attach the heat sink 28 to the III nitride layer 14 side. As can be seen in the FIG. 3B, NP-GaN DBR side is a light emission side, however, the lift off interface to CMP line still a significant III-nitride layer exists but which can be controlled during the CMP polishing itself, wherein contrary to other procedures the layer remained in this invention is grown using ELO, thus it is crystally pure and the interface surface roughness is engineered to be sub-nanometer surface roughness value without introducing CMP or any polishing techniques on the liftoff side. In this particular invention dielectric mask is prepared to be above 300 nm thick and preferably a multilayer combination between SiO₂ and SiN. The surface roughness of the dielectric mask is designed to be below sub-nanometer (e.g. 2 nm) so that same can be replicated on the lift off interface.

FIG. 3C is a sketch of typical dimensions of VCSEL device, where the devices of such kind fabricated in 2D-arrays on the host substrate ELO bars. Preferably, one may integrate a complimentary metal oxide semiconductor logic gate substrates on top of these devices as emission was chosen from the bottom side, i. e from the NP-GaN DBR side as indicated in the small figure.

### Advantages

1. Parallel NP-GaN DBR layers provide thermal stability better than dielectric material.
2. Discrete ELO base layers simplify deep trench defining procedures to access NP layers and ease the activation of p-GaN. 3. Liftoff interface did not require further polishing after removing from host substrate.

### Section 4: Long Cavity VCSELs

### (i) GaN Lens VCSEL

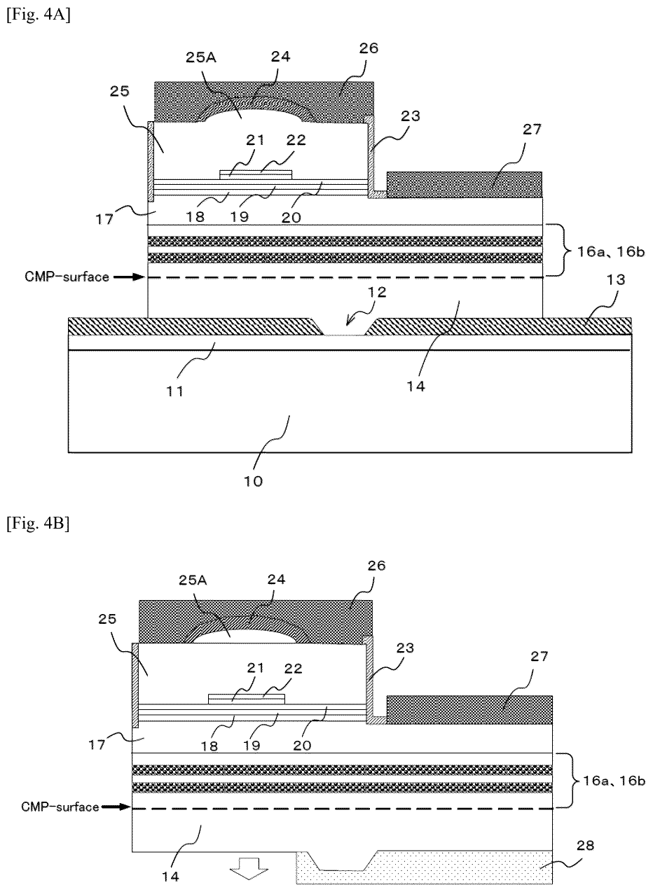

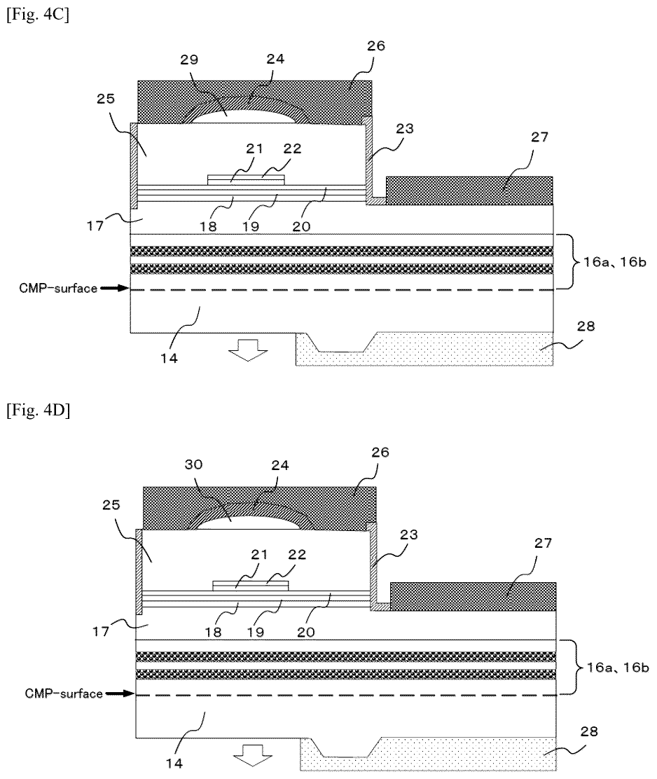

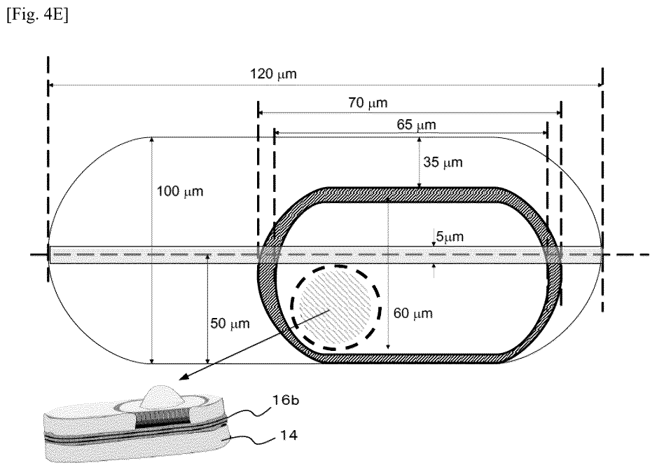

For example, in the case of long cavity VCSEL where cavity thickness is more than 10 λ, after growing a super lattice of NP DBR 16 b assuming light emission designed from NP-GaN DBR 16b so the porosity and the number of DBR layers optimized to achieve a value ~99.5. The device layers for a long cavity >10 λ thick were designed using n-GaN, active region, p-AlGaN 19 and p-GaN 20 and tunnel junction layers 21,22 as indicated. Then a current spread layer 25 to burry tunnel junction is prepared to fit the design parameters as per the long cavity VCSEL requirement. The only difference compared to the short cavity VCSEL is the thickness of the layers used to embed the tunnel junction. In this case rather large thickness n-GaN 27 and UID GaN layers 14 were deployed. FIG. 4A shows a typical design still left on the host substrate.

Current injecting aperture is formally defined during burying process of tunnel junction. After, photoresist lenses were formed via photoresist reflow and imaged onto the thick GaN layer using RIE to form GaN lens 25A. Following this, slightly large mesa is prepared to contact n-GaN layer 17 for the metal contact. This large mesa and the discrete island nature of the ELO bars allow activating p-GaN 20 more effectively. Then an isolation layer 23 is placed to avoid short circuit between p-contact layer 26 and n-contact layer 27. Then selectively a mesa is opened photolithographically on the top of the device centering current aperture on the curved GaN lens 25A. Then a 16-period dielectric DBR 24 made of periods of SiO₂/Ta₂O₅ was deposited on the topside. Next, SiO₂ or a protective film is placed (not shown) to protect devices from NP DBR etch and provide electrical isolation. Next, EC etching was performed on the samples by immersing in oxalic acid against a bias voltage to etch NP DBRs 16b. Then, p-contact and n-contact pads were selectively patterned using photolithography and metal contacts Ti/Au were deposited. Next the VCSEL device is separated from the host substrate resulting picture shown in FIG. 4B. As can be seen in the picture, NP-GaN DBR side is light emission side, however, the lift off interface to CMP line there still a significant III-nitride layer different from the existing conventional devices. Wherein contrary to other procedures the additional layer below NP-GaN DBR 16b in this invention was grown using ELO, thus the crystal quality is superior, and this thickness can be controlled either epitaxially or during the CMP process. Moreover, the interface surface roughness is engineered to below sub-nanometer value without introducing CMP or any polishing techniques, just by simply engineering dielectric mask 13 material and deposition technique. The dielectric mask is prepared to be minimum 300 nm thick and preferably a multilayer combination of SiO₂ and SiN. The surface roughness of the dielectric mask is designed to be below sub-nanometer so that same can be replicated on the lift off interface.

### Advantages

1. Parallel NP-GaN DBR layers provide thermal stability better than dielectric material.
2. Thick cavity GaN lens provides thermal stability for the structure.
3. Discrete ELO base layers simplify deep trench defining procedures to access NP layers and ease the activation of p-GaN.
4. Liftoff interface did not require any polishing after removing from host substrate.
   (ii) Dielectric Lens VCSEL For example, in the case of long cavity VCSEL having a cavity thickness more than 10 λ, after growing a super lattice of NP DBR assuming light emission designed from NP-GaN DBR 16b so the porosity and the number of DBR layers optimized to achieve a value ~99.5. The device layers for a long cavity >10 λ thick which create a problem for the device's active region 18. To fabricate thick GaN lens 25A in the long cavity ~3 μm thick, the n-GaN 25 growth was carried usually at higher temperature than the pre-grown active region 18, thus eventually damages the active region's quantum wells. On the other hand, if the growth temperature of the thick GaN cavity decreased that introduces crystal defects thereby increase in optical absorption resulting ceases lasing action in the VCSEL. To combat this, the lens material can be replaced with a dielectric material, which can be deposited at or near room temperature, preventing degradation of active region 18. The dielectric material is deposited when optical cavity thickness is below 102, i.e. like the short cavity VCSEL thickness described in section 3. A properly optimized dielectric lens material can be nearly lossless. Right after the optical cavity, having a thickness similar to the short cavity is achieved with n-GaN 17, active region 18 and p-GaN 19, 20 and tunnel junction 21, 22 and current spread layers 25, and current injecting aperture is formally defined during burying process of tunnel junction 21, 22. In this design, first, a thick dielectric material, like SiO₂ is deposited on the short cavity GaN device layers. After then photoresist lenses were formed via photoresist reflow and imaged onto the deposited dielectric material using RIE to form dielectric lens. Following this, slightly large mesa is prepared to contact n-GaN region for the metal contact. This mesa and discrete island nature of the ELO bars allow activating p-GaN more effectively. Then an isolation layer 23 is placed to avoid short circuit between p-contact layer 26 and n-contact layer 27. Then selectively a mesa is opened photolithographically on the top of the device centering current aperture on the curved lens. Then a 16-period dielectric DBR 24 made of periods of SiO₂/Ta₂O₅ was deposited on the dielectric lens 29. Next, SiO₂ or a protective film is placed (not shown) to protect devices from NP DBR etch and provide electrical isolation. Next, EC etching was performed on the samples by immersing in oxalic acid against a bias voltage to etch NP DBRs 16b. Then, p-contact and n-contact pads were selectively patterned using photolithography and metal contacts Ti/Au were deposited. Next the VCSEL device is separated from the host resulting a picture shown in FIG. 4C. As can be seen in the picture, NP-GaN DBR 16b side is light emission side, however, the lift off interface to CMP line there still a significant III-nitride layer different from the existing conventional devices. Wherein contrary to other procedures the additional layer below NP-GaN DBR 16b in this invention was grown using ELO, thus the crystal quality is superior, and this thickness can be controlled either epitaxially or during the CMP process. Moreover, the interface surface roughness is engineered to below sub-nanometer value without introducing CMP or any polishing techniques, just by simply engineering dielectric mask material and deposition technique. The dielectric mask 13 is prepared to be minimum 300 nm thick and preferably a multilayer combination of SiO₂ and SiN. The surface roughness of the dielectric mask 13 is designed to be below sub-nanometer so that same can be replicated on the lift off interface.

### Advantages

1. Parallel NP-GaN DBR layers provide thermal stability better than dielectric material.
2. Thick cavity created by dielectric lens is lossless.
3. No active layer damage.
4. Discrete ELO base layers simplify deep trench defining procedures to access. NP layers and ease the activation of p-GaN.
5. Liftoff interface did not require any polishing after removing from host substrate.
   (iii) Air lens VCSEL

This design is similar as dielectric lens VCSEL except transferring curved surface onto dielectric material. The dielectric material is deposited when optical cavity thickness is below 10 λ, like the short cavity VCSEL thickness described in section 3. A properly optimized dielectric lens material can be nearly lossless. Right after the optical cavity, having a thickness similar to the short cavity is achieved with n-GaN 17, active region 18 and p-GaN 19, 20 and tunnel junction 21, 22 and current spread layers 25, current injecting aperture is formally defined during burying process of tunnel junction 21, 22. In this design, first, a thick dielectric material, like SiO₂ is deposited on the short cavity GaN device layers. After then photoresist lenses were formed via photoresist reflow and then depositing a top side DBR directly on the photoresist and then removing the photoresist underneath the lens create an air-gap lens 30. Following this remaining fabrication procedure is similar as above mentioned VCSEL devices.

The device is schematically shown in FIG. 4D.

FIG. 4E is a sketch of typical dimensions of VCSEL device, where the devices of such kind fabricated in 2D-arrays on the host substrate ELO bars. Preferably, one may integrate a complementary metal oxide semiconductor logic gate substrates on top of these devices as emission was chosen from the bottom side, i. e from the NP-GaN DBR 16b side as indicated in the small figure.

### Advantages

1. Parallel NP-GaN DBR layers provide thermal stability better than dielectric material.
2. Thick cavity created by dielectric material is lossless.
3. Air in the lens creats better refractive index contrast thereby provides better re-flection and simplify the process.
4. No active layer damage.
5. Discrete ELO base layers simplify deep trench defining procedures to access NP layers and ease the activation of p-GaN.
6. Liftoff interface did not require any polishing after removing from host substrate.

### Applications

### Lighting

GaN based LEDs have led to dramatic shift in residential and automotive lighting. Lighting in combination with communication services are very desirable in the future smart city and smart infrastructures. VCSELs are better alternatives to LEDs and edge emitting laser diodes. However, not having a proper profitable mass production techniques stopping GaN VCSELs entering market. The procedures developed in the above embodiments can be used to mass produce VCSEL units that applicable in lighting applications.

### Visible Light Communication

Laser light for potential data transfer and communication applications through light fidelity (LiFi). With the rapid increase of IoT devices the demand on data transmission continues to expand. The RF spectrum is getting saturated and new frequencies are needed to keep up with the continuously growing demand. A GaN VCSEL adoption into existing LED architecture is simpler than replacing with an edge emitting laser.

Therefore, the device described in the above embodiments could serve the purpose.

### Near Eye Displays

Near eye displays represent the next major wave of consumer electronics. They are the basis of virtual reality (VR) and augmented reality (AR) technology. Currently, micro-LEDs are predominant choice for displays, however despite the limited progress in VCSEL research, VCSELs must be introduced as miniature display and near eye display. Relatively low optical power is beneficial in maintaining eye safety. Low divergence and circular symmetry reduce additional optical elements thus leads to compactness. The 2D array integration capability of VCSELs is simpler than edge emitting lasers. Therefore, the VCSEL product made using invention can be applied in these applications.

### Advantages

1. Use of a sufficiently long cavity without excessive diffraction loss, with two reflective mirrors defining the VCSEL cavity.
2. Better thermal management due to a long-enough cavity and/or contacts placement on nitride layers.
3. GaN template step included in the device connects with better thermal conducting TO substrate material thereby improves thermal performance.
4. Less costly large template substrates such as GaN on Sapphire can be used to get benefit.
5. GaN substrates with high-quality and larger size are very expensive. The present ELO technique can unlock the usage of foreign substrates in the production of VCSELs.
6. This invention is expected to provide a significant improvement in the performance and reduction in the manufacturing cost and eliminating complex procedures.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

### REFERENCE SIGNS LIST

10 III-nitride-based substrate
11 III-nitride template
12 open area stripe
13 dielectric mask
14 UID GaN layers
15 wing
16a nanoporous GaN DBR section
16b NP DBR
17 n-GaN layer
18 III nitride active layers
19 III-nitride p-type electron blocking layer (EBL)
20 p-type III nitride layer
21 p⁺⁺ GaN layer
22 n⁺⁺ GaN 22
23 isolation layer
24 dielectric DBR
25 current spread layer (n-GaN)
26 p-contact layer
27 n-contact layer
28 heat sink
29 dielectric lens
30 air-gap lens

1. An extended vertical cavity surface emitting laser (VCSEL), comprising:
an epitaxially laterally overgrown semiconductor section, configured by a III-nitride active region between a hole injecting III-nitride layer and an electron injecting III-nitride layer; and
a nanoporous III nitride layer on a side of the electron injecting III nitride layer.

2. The VCSEL according to claim 1, further comprising a curved or flat mirror on a side of the hole injecting III-nitride layer and a flat mirror on the electron injecting III-nitride layer side.

3. The VCSEL according to claim 1, further comprising a nanoporous III-nitride GaN layer disposed between an unintentionally doped (UID) GaN layer and the III-nitride active region.

4. The VCSEL according to claim 3, wherein the UID GaN layer is substantially not included in a III-nitride template.

5. The VCSEL according to claim 3, wherein the UID GaN layer is formed via epitaxial lateral overgrowth.

6. The VCSEL according to claim 3, wherein an interface with the UID GaN layer is not included in a host substrate but is part of a VCSEL optical cavity.

7. The VCSEL according to claim 3, wherein an interface surface between the UID GaN layer and a dielectric mask has a roughness of sub-nanometer dimensions.

8. The VCSEL according to claim 7, wherein no chemical mechanical polishing (CMP) or etching or grinding was used to smoothen the interface surface of the UID GaN layer.

9. The VCSEL according to claim 2, wherein the flat mirror on the hole injecting III-nitride layer side comprises a dielectric mirror for short cavity VCSEL.

10. The VCSEL according to claim 2, wherein the curved mirror, which is disposed on or above a p-GaN layer, has a GaN lens.

11. The VCSEL according to claim 2, wherein the curved mirror, which is disposed on or above a p-GaN layer, has a dielectric lens.

12. The VCSEL according to claim 11, wherein a material of the dielectric lens comprises a transparent oxide.

13. The VCSEL according to claim 11, wherein a material of the dielectric lens comprises a polymer.

14. The VCSEL according to claim 2, wherein the curved mirror, which is disposed on or above a p-GaN layer, has an air lens.

15. The VCSEL according to claim 1, further comprising a curved DBR comprising a dielectric DBR.

16. The VCSEL according to claim 1, wherein a crystal orientation of the III-nitride layers is c-plane, semipolar or non-polar.

17. A method for fabricating a vertical cavity surface emitting laser (VCSEL), the method comprising:
forming a III-nitride template on a substrate;
forming a dielectric mask on the III-nitride template;
forming UID GaN by epitaxial growth from an open area of the dielectric mask; and
forming a nanoporous GaN DBR on the UID GaN.

18. The method according to claim 17, wherein the nanoporous GaN DBR includes a plurality of DBR mirrors.
